(19) United States
(12) Patent Application Publication
(10) Pub. No.: US 2025/0336444 A1
(43) Pub. Date: Oct. 30, 2025

(54) MEMORY SYSTEMS, MEMORYS, AND OPERATION METHODS OF THE MEMORYS

(71) Applicant: Yangtze Memory Technologies Co., Ltd., Wuhan (CN)

(72) Inventors: Pengyu Xu, Wuhan (CN); Ying Huang, Wuhan (CN); HongTao Liu, Wuhan (CN); Yuanyuan Min, Wuhan (CN); Kaikai You, Wuhan (CN); Xinran Li, Wuhan (CN)

(21) Appl. No.: 18/787,603

(22) Filed: Jul. 29, 2024

(30) Foreign Application Priority Data
Apr. 24, 2024 (CN) 202410501858.X

(51) Int. Cl. G11C 16/16; G11C 16/24

(52) U.S. Cl. CPC G11C 16/16; G11C 16/24

(57) ABSTRACT

The present disclosure provides a memory system, a memory, and an operation method of a memory. The memory system includes a memory and a memory controller coupled with the memory. The memory controller is configured to: send an erase operation instruction to the memory, the erase operation instruction including information of a memory block having data to be erased in the memory. The memory is configured to: in response to the erase operation instruction, set a dummy word line coupled with the memory block to a floating state when a bit line voltage or a source line voltage of the memory block rises to a first voltage, wherein the first voltage is related to an erase count of the memory block.

### CROSS-REFERENCE TO RELATED APPLICATION

This application claims priority to and the benefit of Chinese Patent Application 202410501858.X, filed on Apr. 24, 2024, which is hereby incorporated by reference in its entirety.

### TECHNICAL FIELD

The present disclosure pertains to the technical field of semiconductor chips, and particularly relates to memory systems, memorys, and operation methods of the memorys.

### BACKGROUND

A flash memory is a memory having the characteristics such as data nonvolatility, fast read and write speeds, low power consumption, and long service life, and is widely applied to various electronic products, such as a mobile phone, a computer, a smart sensor, and a positioning apparatus.

### BRIEF DESCRIPTION OF THE DRAWINGS

In order to illustrate the technical solutions in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limiting an actual size of a product, an actual flow of a method, an actual timing of a signal, etc. involved in the examples of the present disclosure.

FIG. 1 is a schematic structural diagram of a memory provided by examples of the present disclosure;

FIG. 2 is a schematic structural diagram of a memory array provided by examples of the present disclosure;

FIG. 3 is a local cross-sectional schematic view of a memory string provided by examples of the present disclosure;

FIG. 4 is a schematic diagram of a voltage application for an erase operation on a memory block provided by examples of the present disclosure;

FIG. 5 is a schematic diagram of a path for electrons entering a dummy memory cell provided by examples of the present disclosure;

FIG. 6 is a schematic diagram of a comparison between threshold voltage distributions of the dummy memory cell before and after a plurality of erase operations under an over-high release voltage provided by examples of the present disclosure;

FIG. 7 is a schematic diagram of a path for electrons flowing Fout of the dummy memory cell provided by examples of the present disclosure;

FIG. 8 is a schematic diagram of a comparison between threshold voltage distributions of the dummy memory cell before and after a plurality of erase operations under an over-low release voltage provided by examples of the present disclosure;

FIG. 9 is a schematic diagram of a comparison between threshold voltage distributions of the dummy memory cell before and after a plurality of erase operations under an appropriate release voltage provided by examples of the present disclosure;

FIG. 10 is a schematic structural diagram of a memory system provided by examples of the present disclosure;

FIG. 11 is a schematic diagram of an information interaction between a memory and a memory controller provided by examples of the present disclosure;

FIG. 12 is a schematic diagram of a comparison between a bit line/source line voltage, a word line voltage, and a dummy word line voltage during an erase operation provided by examples of the present disclosure;

FIG. 13 is a schematic structural diagram of a memory and a peripheral circuit thereof provided by examples of the present disclosure; and

FIG. 14 is a schematic flow diagram of an operation method of a memory provided by examples of the present disclosure.

### REFERENCE NUMERALS

100: memory;
110: memory array;
120: peripheral circuit;
121: control logic;
122: I/O interface;
123: voltage generator;
124: column decoder;
125: row decoder;
126: page buffer;
127: data bus;
128: register;
200: memory block;
210: memory string;
211: top select gate;
212: memory cell;
213: dummy memory cell;
214: bottom select gate;
310: substrate;
320: memory stack;
321: gate conductive layer;
322: dielectric layer;
330: heavily doped joint;
410: bit line;
420: source line;
430: string select line;
440: word line;
450: dummy word line;
460: ground select line;
400: memory system; and
500: memory controller.

### DETAILED DESCRIPTION

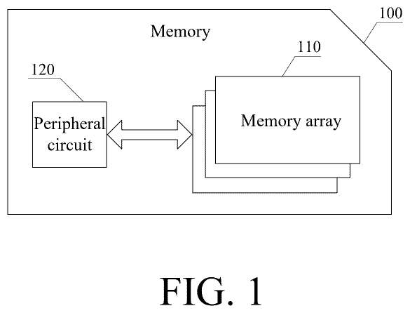

The technical solutions in some examples of the present disclosure will be described clearly and completely below in conjunction with FIG. 1-FIG. 14. Apparently, the examples described are only part of, but not all of, the examples of the present disclosure. All other examples obtained by those of ordinary skill in the art based on the examples provided by the present disclosure shall fall in the scope of protection of the present disclosure.

Unless otherwise specified in the context, throughout the specification and the claims, the term “comprising” is interpreted as an open and inclusive meaning, i.e., “including, but not limited to”. In the description of the specification, the terms “one example”, “some examples”, “an example”, or “in an example”, etc. are intended to indicate that particular features, structures, materials, or characteristics related to the example or implementation are included in at least one example or implementation of the present disclosure. The schematic representation of the above terms may not necessarily refer to the same example or implementation. Furthermore, these particular features, structures, materials, or characteristics may be included in any one or more examples or implementations in any suitable manner.

In the following, the terms “first” and “second”, etc. are only for the purpose of description, and shall not be construed as indicating or implying relative importance or implicitly indicating the number of indicated technical features. Thus, features defined by “first” and “second” may explicitly or implicitly include one or more of such features. In the description of the examples of the present disclosure, “a plurality of”' means two or more, unless otherwise stated.

In describing some examples, expressions such as “coupled” and derivatives thereof may be used. For example, the term “coupled” may be used in the description of some examples to indicate that two or more components have a direct physical contact or an electrical contact. In this case, “coupled” may be also described as “connected”. Moreover, the term “coupled” may also mean that two or more components have no direct contact with each other, but still cooperate or interact with each other. The examples disclosed herein are not necessarily limited to the content herein.

The use of “configured to” herein means open and inclusive language, and does not exclude an apparatus suitable for performing or configured to perform additional tasks.

With the increasing requirements of consumers for the performance and reliability of the electronic products, the market imposes higher requirements for the read speed, write (which may also be referred to as program) speed, and service life, etc. of the flash memory.

A three-dimensional (3-Dimension, 3D) memory is a memory having stacked layers. As shown in FIG. 1, in some implementations, a memory 100 may include a memory array 110 and a peripheral circuit 120 coupled to the memory array 110, wherein the memory array 110 may be of a NAND architecture or a NOR architecture.

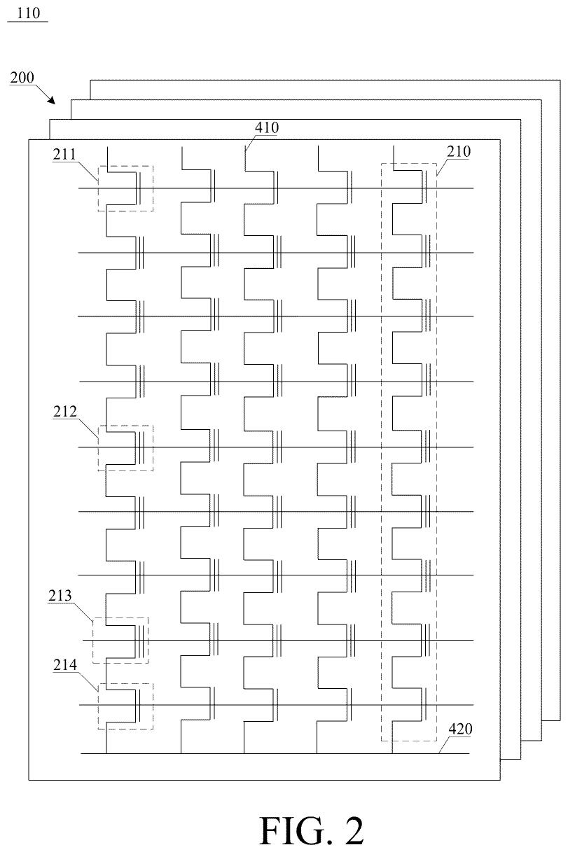

As shown in FIG. 2, in some implementations, the memory array 110 may comprise a plurality of memory blocks 200, and each memory block 200 may comprise a plurality of memory strings 210, wherein each memory string 210 may comprise a top select gate (TSG) 211, a plurality of memory cells 212, a dummy memory cell 213, and a bottom select gate (BST) 214 that are stacked and serially sequentially. One end of the memory string 210 is coupled with a bit line (BL) 410, and the other end of the memory string 210 is coupled with a source line (SL) 420.

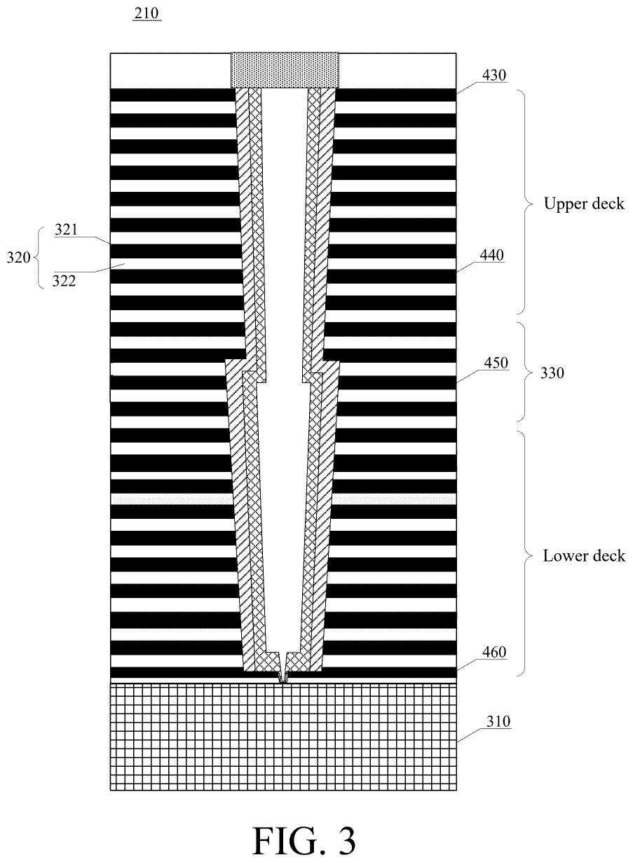

FIG. 3 illustrates a local cross-sectional schematic view of a possible memory string 210 of the present disclosure. The memory string 210 may extend through a memory stack 320 vertically above a substrate 310. Due to limitations of an etching process, in some implementations, a plurality of decks may be formed through multiple times of etching, and an upper deck and a lower deck adjacent to each other may be connected tightly by forming a heavily doped joint 330 therebetween, so as to increase the number of stacked layers in the memory stack 320. Heavy doping refers to a case where a semiconductor material is doped with a larger amount of impurities, and the heavily doped joint 330 is configured to ensure that a tight connection relationship may be formed between two decks. In some examples, channels in the upper deck and the lower deck may be communicated (as shown in FIG. 3). In some other examples, the channels in the upper deck and the lower deck may be not communicated (not shown in the drawings).

In some implementations, the substrate 310 may include silicon (e.g., monocrystalline silicon), silicon germanium (SiGe), gallium arsenide (GaAs), germanium (Ge), silicon on insulator (SOI), germanium on insulator (GOI), or any other suitable materials. The memory stack 320 may comprise alternating gate conductive layers 321 and dielectric layers 322. The number of the gate conductive layers 321 and the dielectric layers 322 in the memory stack 320 may determine the number of the memory cells 212 in the memory string 210. Gate conductive layer 321 may comprise a conductive material, including, but not limited to, tungsten (W), cobalt (Co), copper (Cu), aluminum (Al), polycrystalline silicon, doped silicon, silicide, or any combinations thereof.

Each gate conductive layer 321 may comprise a control gate surrounding the memory cell 212, and the gate conductive layer 321 at the top of the memory stack 320 may extend laterally as a string select line (SSL) 430, the gate conductive layer 321 at the bottom of the memory stack 320 may extend laterally as a ground select line (GSL) 460, or the gate conductive layer 321 between the string select line 430 and the ground select line 460 may extend laterally as a word line (WL) 440 or dummy word line (dummy WL) 450

As shown in FIG. 3, in some implementations, the dummy word line 450 is disposed near the heavily doped joint 330. In some implementations, the dummy word line 450 may be also disposed between the string select line 430 and the word line 440, between the word line 440 and the ground select line 460, or between the word line 440 and another word line 440. The position and number of the disposed dummy word line 450 may be changed adaptively, and the present disclosure is not limited in this regard.

Like the word line 440, the dummy word line 450 may have the same conductive layer structure as the word line 440, and in some examples, the dummy word line 450 may be formed simultaneously with the word line 440 using the same process. Unlike the word line 440, the dummy memory cell 213 coupled with the dummy word line 450 does not store data. In some examples, the dummy memory cell 213 coupled with the dummy word line 450 may have no any connection with the bit line 410, and thus is unable to transmit data to the bit line 410. The dummy word line 450 may reduce noise interference to the word line 440. In some examples, by providing the dummy memory cell 213, capacitive coupling noise between a select gate (e.g., the top select gate 211 or the bottom select gate 214) and the memory cell 212 can be reduced by 50%, thereby reducing program disturbance, read failure, and erase failure, etc. caused by the coupling noise.

It is to be understood that, although not shown in FIG. 3, additional components of the memory array 110 may be formed, including, but not limited to, a gate line slit/source contact, a local contact, and an interconnect layer, etc.

In some implementations, the memory cell 212 may be a device capable of storing charge, such as a floating gate transistor or a charge trap field effect transistor, and the memory cell 212 can store data by storing charge. In some examples, the memory cell 212 may store charge through a program operation to write data “0”, and remove charge through an erase operation to write data “1”.

In some implementations, the memory block 200 is a minimum unit for the erase operation. During the erase operation on the memory block 200, an erase voltage Vₑᵣₐ is applied to the bit line 410 (or the source line 420) coupled with the memory block 200, and a ground voltage Vₛₛ is applied to the word line 440 coupled with the memory block 200. As such, a larger voltage difference is formed between a channel voltage and a gate voltage of the memory block 200, and the larger voltage difference causes holes in a channel to combine with electrons in the memory cell 212, so as to erase data of the memory cell 212 in the memory block 200.

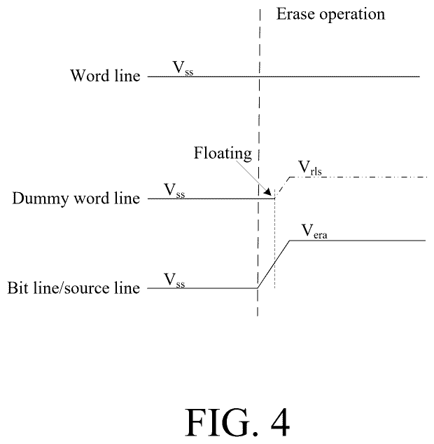

The dummy memory cell 213 in the memory block 200 does not require programming. Therefore, in some implementations, the erase operation is required to prevent the dummy memory cell 213 coupled with the dummy word line 450 from being erased. As shown in FIG. 4, during the erase operation, a hold & release operation is performed on the dummy word line 450. That is, the dummy word line 450 is set to be floating when a bit line voltage (or source line voltage) coupled with the memory block 200 reaches a certain voltage value. As such, through carrier interactions within the memory array 110, there is always a certain voltage difference maintained between a voltage of the dummy word line 450 and the erase voltage, so as to reduce or even avoid combinations of electrons in the dummy memory cell 213 with holes in the channel, thereby preventing the dummy memory cell 213 from being erased.

Those skilled in the art will understand that in this specification, when one element (or component, assembly, member, etc.) is referred to as being in a floating state, it is intended to indicate that the element (or component, assembly, member, etc.) does not form an electrical pathway with another element (or component, assembly, member, etc.).

As shown in FIG. 4, during the erase operation, when the dummy word line 450 is set to the floating state, due to voltage coupling, the voltage of the dummy word line 450 rises as the bit line voltage (or the source line voltage) continues to rise, so that there is always a certain voltage difference maintained between the voltage of the dummy word line 450 and the erase voltage. When the bit line voltage (or the source line voltage) rises to the erase voltage Vₑᵣₐ, the voltage of the dummy word line 450 rises to a release voltage Vᵣₗₛ, wherein the release voltage Vᵣₗₛ is greater than the ground voltage Vₛₛ.

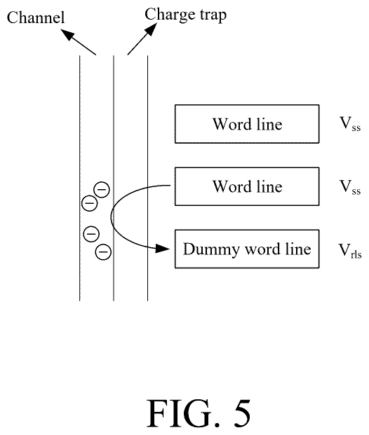

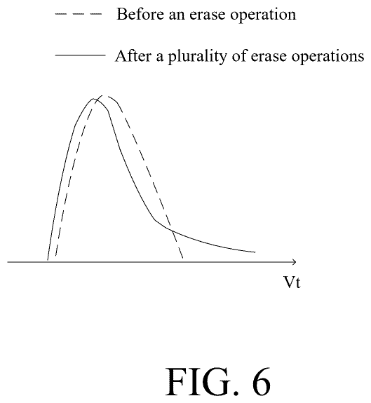

As shown in FIG. 5, during the erase operation, the ground voltage Vₛₛ is applied to the word line 440, so that electrons in the memory cell 212 enter a charge trap (or a floating gate layer) of the dummy memory cell 213 through the channel. Therefore, after a plurality of erase operations, a threshold voltage of the dummy memory cell 213 drifts rightward, causing a threshold voltage distribution to become narrower (as shown in FIG. 6). When the release voltage Vᵣₗₛ is higher, a difference between the release voltage Vᵣₗₛ and the ground voltage Vₛₛ is larger, so that the number of the electrons entering the charge trap (or the floating gate layer) of the dummy memory cell 213 is larger, and thus the rightward drift of the threshold voltage of the dummy memory cell 213 is more severe.

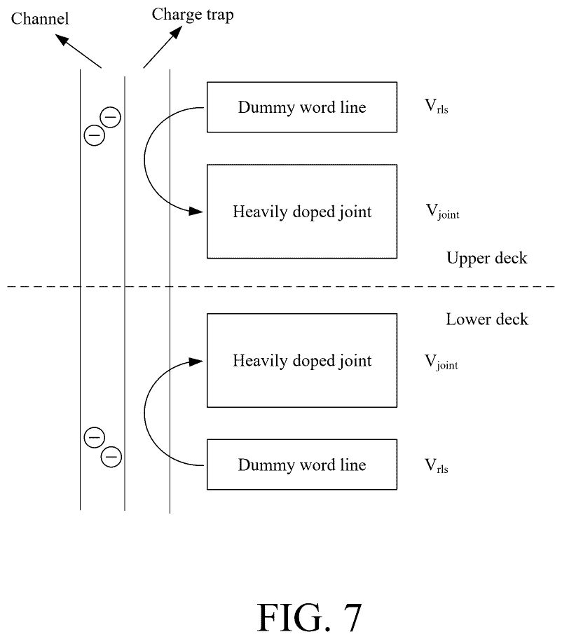

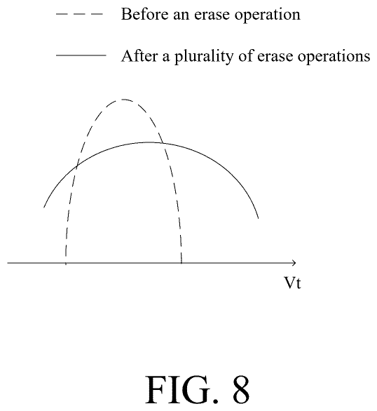

As shown in FIG. 7, during the erase operation, a gate voltage Vⱼₒᵢₙₜ of the heavily doped joint 330 becomes higher than the release voltage Vᵣₗₛ of the dummy word line 450 through potential coupling, so that electrons flow out of the charge trap (or the floating gate layer) of the dummy memory cell 213 through the channel. Therefore, after a plurality of erase operations, the threshold voltage of the dummy memory cell 213 drifts leftward, causing the threshold voltage distribution to become wider (as shown in FIG. 8). When the release voltage Vᵣₗₛ is lower, a difference between gate voltage Vⱼₒᵢₙₜ of the heavily doped joint 330 and the release voltage Vᵣₗₛ is larger, so that the number of the electrons flowing out of the charge trap (or the floating gate layer) of the dummy memory cell 213 is larger, and thus the leftward drift of the threshold voltage of the dummy memory cell 213 is more severe.

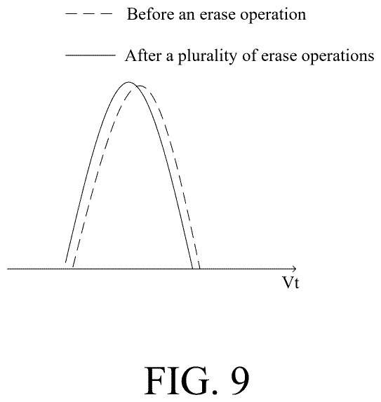

It is to be understood that a balance between the electrons entering and flowing out of the charge trap (or the floating gate layer) of the dummy memory cell 213 is required to be kept, so that an appropriate threshold voltage distribution of the dummy memory cell 213 may be guaranteed after the plurality of erase operations (as shown in FIG. 9). However, practical use indicates that in an erasing process, as an erase count of the memory block 200 increases, a proportion of the electrons flowing out of the charge trap (or the floating gate layer) of the dummy memory cell 213 increases, so that the threshold voltage of the dummy memory cell 213 drifts leftward, causing the threshold voltage distribution to become narrower, which affects the service life of the memory 100.

During the erase operation on the memory block 200, in the implementations of the present disclosure, the dummy word line 450 coupled with the memory block 200 is set to the floating state when the bit line voltage (or the source line voltage) coupled with the memory block 200 rises to a first voltage, wherein the first voltage is related to the erase count of the memory block. In the implementations of the present disclosure, the first voltage is related to the erase count of the memory block, so that a moment of setting the dummy word line 450 to the floating state is adjustable during the erase operation to adjust the release voltage on the dummy word line 450. The balance between the electrons entering and flowing out of the charge trap (or the floating gate layer) of the dummy memory cell 213 is kept by adjusting the release voltage, so as to guarantee that the threshold voltage of the dummy memory cell 213 is stable, thereby improving the service life of the memory 100.

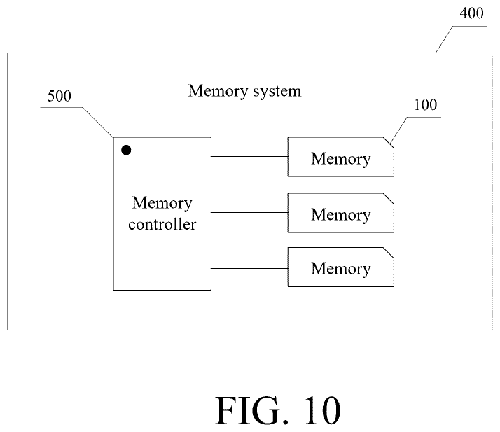

As shown in FIG. 10, examples of the present disclosure provide a memory system 400 comprising the memory 100 and a memory controller 500, wherein the memory controller 500 is coupled with the memory 100 and configured to control the memory 100. The memory controller 500 and one or more memories 100 may be integrated into various types of end electronic products, e.g., be included in the same package, such as a universal flash storage (UFS) package or an embedded multi media card (eMMC) package. That is, the memory system 400 may be implemented and packaged into different types of end electronic products. In some examples, the memory controller 500 and a single memory 100 may be integrated into a memory card. The memory card may include a personal computer memory card international association (PCMCIA) card, a compact flash (CF) card, a smart media (SM) card, a memory stick, a multi-media card (MMC), and a secure digital (SD) card, etc. The memory card may further comprise a memory card connector coupling the memory card with a host. In some other examples, the memory controller 500 and a plurality of memories 100 may be integrated into a solid state disk (SSD). The solid state disk may further comprise a solid state disk connector coupling the solid state disk with a host. In some implementations, at least one of a storage capacity or an operation speed of the solid state disk is greater than that of the memory card.

In some implementations, the memory system 400 may be applied to different types of electronic apparatuses, such as a mobile phone (e.g. a cellphone), a desktop computer, a tablet computer, a notebook computer, a server, a vehicle apparatus, a gaming console, a printer, a positioning apparatus, a wearable apparatus, a smart sensor, a mobile power supply, a virtual reality (VR) apparatus, an augmented reality (AR) apparatus, a server, or any other electronic apparatuses capable of storing data.

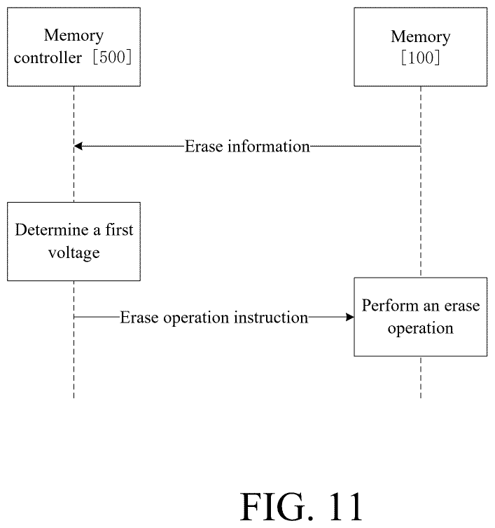

As shown in FIG. 11, in some implementations, the memory controller 500 may receive erase information sent by the memory 100, wherein the erase information may indicate the erase count corresponding to the memory block 200. The memory controller 500 may determine the first voltage based on the erase count of the memory block. The first voltage is smaller when the erase count of the memory block is larger.

In some examples, the memory controller 500 may determine the first voltage based on a preset formula V₁=V_{fresh}−n×V_{offset} according to the erase count of the memory block, wherein V₁ is the first voltage, V_{fresh} is a preset initial first voltage, n is the erase count of the memory block, and V_{offset} is a preset offset voltage. In some other examples, the memory controller 500 may determine the first voltage by querying a preset mapping table according to the erase count, wherein the mapping table comprises a mapping relationship between the erase count and the first voltage.

In some implementations, the memory controller 500 may be configured to send an erase operation instruction to the memory 100, the erase operation instruction comprising information of the memory block 200 having data to be erased in the memory 100, and information of the first voltage. The information of the memory block 200 is configured to instruct the memory 100 to perform the erase operation on the memory block 200 having the data to be erased, and the information of the first voltage is configured to instruct the memory 100 to set the dummy word line 450 coupled with the memory block 200 to the floating state when the bit line voltage (or the source line voltage) of the memory block 200 rises to the first voltage.

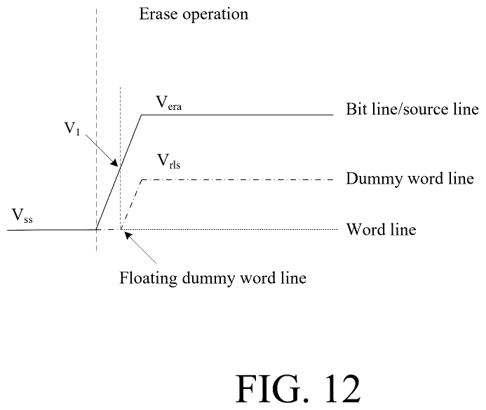

The memory 100 receives the erase operation instruction from the memory controller 500, so as to perform the erase operation on the memory block 200 having the data to be erased. As shown in FIG. 12, in some implementations, when performing the erase operation, the memory 100 applies the erase voltage Vₑᵣₐ to the bit line 410 (or the source line 420) coupled with the memory block 200, and applies a second voltage to the word line 440 and the dummy word line 450 coupled with the memory block 200. In some examples, the second voltage comprises the ground voltage Vₛₛ. The dummy word line 450 is set to the floating state when the bit line voltage (or the source line voltage) coupled with the memory block 200 rises to the first voltage. As a result, the release voltage is equal to a difference between the erase voltage and the first voltage (i.e., Vᵣₗₛ=Vₑᵣₐ−V₁), wherein the erase voltage Vₑᵣₐ is greater than the first voltage V₁. A voltage difference between the erase voltage Vₑᵣₐ and the ground voltage Vₛₛ may be such that the electrons in the memory cell 212 are neutralized by the holes in the channel, so as to erase the memory cell 212. A voltage difference between the erase voltage Vₑᵣₐ and the release voltage Vᵣₗₛ is insufficient to cause the electrons in the dummy memory cell 213 to be neutralized by the holes in the channel, so as to avoid erasing the dummy memory cell 213.

In the erasing process, as the erase count of the memory block 200 increases, a proportion of the electrons flowing out of the charge trap (or the floating gate layer) of the dummy memory cell 213 increases. In the implementations of the present disclosure, during the erase operation, the first voltage V₁ decreases as the erase count of the memory block 200 increases, so that the dummy word line 450 will be set to the floating state earlier, and thus the release voltage Vᵣₗₛ on the dummy word line 450 rises as the erase count of the memory block 200 increases. As shown in FIG. 5, when the release voltage Vᵣₗₛ is higher, the number of the electrons entering the charge trap (or the floating gate layer) of the dummy memory cell 213 is larger. As shown in FIG. 7, when the release voltage Vᵣₗₛ is higher, the number of the electrons flowing out of the charge trap (or the floating gate layer) of the dummy memory cell 213 is smaller. As such, the balance between the electrons entering and flowing out of the charge trap (or the floating gate layer) of the dummy memory cell 213 is kept, so as to guarantee that the threshold voltage of the dummy memory cell 213 is stable, thereby improving the service life of the memory 100.

It is to be understood that the memory controller 500 may also perform any other suitable functions, e.g., formatting the memory 100. For example, the memory controller 500 may communicate with an external apparatus (e.g., a host) through at least one of various interface protocols. The interface protocol may include at least one of a universal serial bus (USB) protocol, a multi media card (MMC) protocol, a peripheral component interconnect (PCI) protocol, a PCI-Express (PCI-E) protocol, an advanced technology attachment (ATA) protocol, a serial ATA protocol, a parallel ATA protocol, a small computer system interface (SCSI), an enhanced small disk interface (ESDI) protocol, and an integrated drive electronics (IDE) protocol.

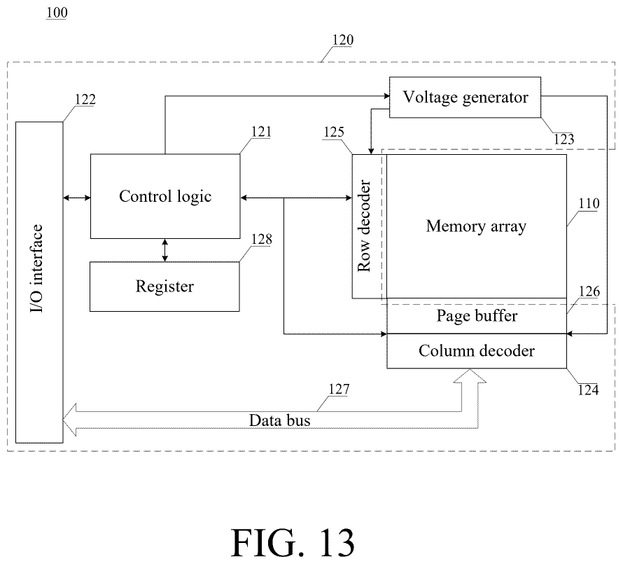

As shown in FIG. 13, the implementations of the present disclosure provide a memory 100. The memory 100 may comprise a peripheral circuit 120 and the memory array 110 as shown in FIG. 2. The memory array 110 is coupled with the peripheral circuit 120 through the string select line 430, the word line 440, the ground select line 460, and the bit line 410, etc. The peripheral circuit 120 is configured to control the memory array 110 to implement, e.g., a program operation, a read operation, and an erase operations, etc. In some implementations, as shown in FIG. 13, the peripheral circuit 120 comprises a control logic 121, an I/O interface 122, a voltage generator 123, a column decoder 124, a row decoder 125, a page buffer 126, a data bus 127, and a register 128. It is to be understood that in some examples, additional circuits not shown in FIG. 13 may be included as well.

The control logic 121 may be coupled to the I/O interface 122, the voltage generator 123, the column decoder 124, the row decoder 125, and the page buffer 126, etc., and is configured to control operations of the row decoder 125, the column decoder 124, the page buffer 126, and the voltage generator 123 in response to a command (CMD) from the memory controller 500. In some examples, the command may comprise a program operation instruction, a read operation instruction, and an erase operation instruction, etc.

The I/O interface 122 may be coupled to the control logic 121, and act as a control buffer to buffer a control instruction (e.g., the erase operation instruction) received from the memory controller 500 (e.g., the memory controller 500 in FIG. 10) and send the control instruction to the control logic 121. In some implementations, the erase operation instruction comprises the information of the memory block 200 having the data to be erased in the memory 100, and the information of the first voltage. The information of the memory block 200 is configured to instruct the control logic 121 to perform the erase operation on the memory block 200 having the data to be erased, and the information of the first voltage is configured to instruct the control logic 121 to set the dummy word line 450 coupled with the memory block 200 to the floating state when the bit line voltage (or the source line voltage) of the memory block 200 rises to the first voltage. The I/O interface 122 may also buffer status information (e.g., erase information) received from the control logic 121 and send the status information to the memory controller 500. In some implementations, the erase information indicates the erase count corresponding to the memory block 200. The I/O interface 122 may be also coupled to the page buffer 126 through the data bus 127, and act as a data I/O interface 122 and a data buffer to buffer and relay data to and from the memory array 110.

The voltage generator 123 may be of an external supply voltage or an internal supply voltage to generate various voltages for performing operations such as erase, program, read, verify, etc. on the memory array 110, such as the program voltage V_{pgm}, the erase voltage Vₑᵣₐ, the ground voltage Vₛₛ, etc., or combinations thereof applied to the word line 440.

The column decoder 124 may apply a voltage generated by the voltage generator 123 to the bit line 410 (or the source line 420) coupled with the memory block 200 in response to control of the control logic 121. In some examples, the column decoder 124 may apply the erase voltage Vₑᵣₐ generated by the voltage generator 123 to the bit line 410 (or the source line 420) coupled with the memory block 200, so as to perform the erase operation on the memory block 200.

The row decoder 125 may apply a voltage generated by the voltage generator 123 to the word line 440 and the dummy word line 450 coupled with the memory block 200 in response to control of the control logic 121. In some examples, the row decoder 125 may apply the ground voltage Vₛₛ generated by the voltage generator 123 to the word line 440 and the dummy word line 450 coupled with the memory block 200, and set the dummy word line 450 coupled with the memory block 200 to the floating state when the bit line voltage (or the source line voltage) of the memory block 200 rises to the first voltage, so as to cooperate with the column decoder 124 to perform the erase operation on the memory block 200.

The page buffer 126 may read data from the memory array 110 and program (write) data to the memory array 110 according to control signals from the control logic 121. In one example, the page buffer 126 may store program data (write data) to be programmed into the memory array 110. In another example, the page buffer 126 may perform a program verify operation to ensure that the data has been properly programmed into the memory cell 212 coupled to the selected word line 440. In still another example, the page buffer 126 may also detect a low power signal from the bit line 410 that represents a data bit stored in the memory cell 212, and amplify a small voltage swing to a recognizable logic level in the read operation.

The register 128 may be coupled to the control logic 121 and include a status register, a command register, and an address register for storing status information, a command operation code (OP code), and a command address for controlling operations of each peripheral circuit 120.

It is to be understood by those skilled in the art that operations performed by the row decoder 125, the page buffer 126, the control logic 121, and the voltage generator 123 described in the present disclosure may be performed by a processing circuit. The processing circuit may include, but is not limited to, hardware of a logic circuit, or a hardware/software combination such as a processor that executes software.

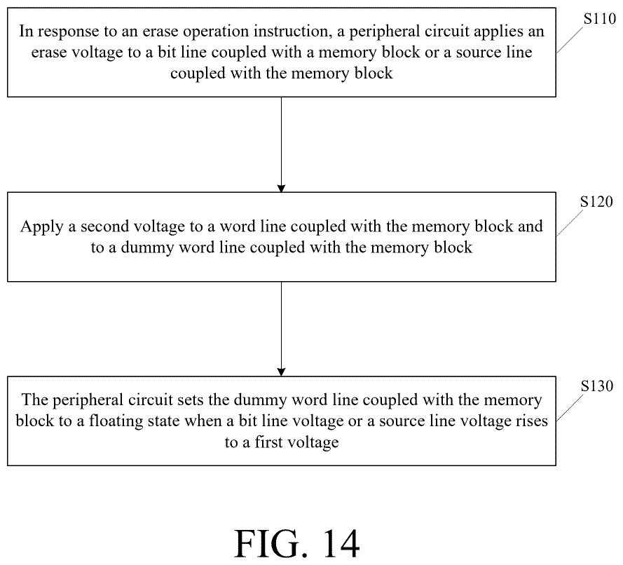

The implementations of the present disclosure further provide an operation method of a memory. As shown in FIG. 14, the operation method comprises operations S110-S130 as follows.

At S110, in response to the erase operation instruction, the peripheral circuit applies the erase voltage to the bit line coupled with the memory block or the source line coupled with the memory block.

In some implementations, the erase operation instruction comprises the information of the memory block 200 having the data to be erased. The peripheral circuit 120 may perform the erase operation on the memory block 200 according to the information of the memory block 200. The erase voltage generated by the voltage generator 123 is applied to the word line 440 or the source line 420 coupled with the memory block 200 through the column decoder 124.

At S120, the second voltage is applied to the word line coupled with the memory block 200 and to the dummy word line coupled with the memory block.

In some implementations, the second voltage comprises the ground voltage. As such, a larger voltage difference is produced between a gate of the memory cell 212 in the memory block 200 and the channel, so that the holes in the channel neutralize the electrons in the memory cell 212, that is, the electrons in the memory cell 212 are removed, thereby erasing the data stored by the memory cell 212 in the memory block 200.

At S130, the peripheral circuit sets the dummy word line coupled with the memory block to the floating state when the bit line voltage or the source line voltage rises to the first voltage.

In some implementations, the erase operation instruction comprises the information of the first voltage, the erase voltage is greater than the first voltage, and the first voltage is related to the erase count of the memory block, wherein the first voltage is smaller when the erase count of the memory block is larger. As such, during the erase operation, the first voltage decreases as the erase count of the memory block 200 increases, so that the dummy word line 450 will be set to the floating state earlier, and thus the release voltage (the release voltage is equal to the difference between the erase voltage and the first voltage) on the dummy word line 450 rises as the erase count of the memory block 200 increases. When the release voltage is higher, the number of the electrons entering the charge trap (or the floating gate layer) of the dummy memory cell 213 is larger; and the number of the electrons flowing out of the charge trap (or the floating gate layer) of the dummy memory cell 213 is smaller. As such, the problem that the proportion of the electrons flowing out of the charge trap (or the floating gate layer) of the dummy memory cell 213 increases due to the increase in the erase count of the memory block 200 is alleviated or even eliminated. The balance between the electrons entering and flowing out of the charge trap (or the floating gate layer) of the dummy memory cell 213 is kept, so as to guarantee that the threshold voltage of the dummy memory cell 213 is stable, which improves the service life of the memory 100.

In some implementations, the peripheral circuit 120 sends the erase information to the memory controller 500, the erase information indicating the erase count corresponding to the memory block. In some examples, the memory controller 500 may determine the first voltage based on the preset formula V₁=V_{fresh}−n×V_{offset} according to the erase count of the memory block, wherein V₁ is the first voltage, V_{fresh} is the preset initial first voltage, n is the erase count of the memory block, and V_{offset} is the preset offset voltage. In some other examples, the memory controller 500 may determine the first voltage by querying the preset mapping table according to the erase count, wherein the mapping table comprises the mapping relationship between the erase count and the first voltage.

Examples of the present disclosure provide a memory system, a memory, and an operation method of a memory. The memory system comprises a memory and a memory controller coupled with the memory. The memory controller is configured to: send an erase operation instruction to the memory, the erase operation instruction comprising information of a memory block having data to be erased in the memory. The memory is configured to: in response to the erase operation instruction, set a dummy word line coupled with the memory block to a floating state when a bit line voltage or a source line voltage of the memory block rises to a first voltage, wherein the first voltage is related to an erase count of the memory block. In the implementations of the present disclosure, during the erase operation, the first voltage decreases as the erase count of the memory block increases, so that the dummy word line will be set to the floating state earlier, and thus the release voltage (the release voltage is equal to the difference between the erase voltage and the first voltage) on the dummy word line rises as the erase count of the memory block increases. When the release voltage is higher, the number of the electrons entering the charge trap (or the floating gate layer) of the dummy memory cell is larger; and the number of the electrons flowing out of the charge trap (or the floating gate layer) of the dummy memory cell is smaller. As such, the problem that the proportion of the electrons flowing out of the charge trap (or the floating gate layer) of the dummy memory cell increases due to the increase in the erase count of the memory block is alleviated or even eliminated. The balance between the electrons entering and flowing out of the charge trap (or the floating gate layer) of the dummy memory cell is kept, so as to guarantee that the threshold voltage of the dummy memory cell is stable, which improves the service life of the memory.

Examples of the present disclosure provide a computer readable storage medium storing a computer executable instruction that, after being executed, may implement the method as shown in FIG. 14.

Examples of the present disclosure provide a computer apparatus comprising a processor and a readable storage medium coupled with the processor, wherein the readable storage medium stores an executable instruction that, when being executed by the processor, may implement the method as shown in FIG. 14.

Examples disclosed by the present disclosure provide a memory system, a memory, and an operation method of a memory for increasing a service life of the memory.

In order to achieve the above object, examples of the present disclosure employ the following technical solution.

In a first aspect, a memory system is provided. The memory system comprises a memory and a memory controller coupled with the memory. The memory controller is configured to: send an erase operation instruction to the memory, the erase operation instruction comprising information of a memory block having data to be erased in the memory. The memory is configured to: in response to the erase operation instruction, set a dummy word line coupled with the memory block to a floating state when a bit line voltage or a source line voltage of the memory block rises to a first voltage, wherein the first voltage is related to an erase count of the memory block.

In some possible implementations, the memory is further configured to: send erase information to the memory controller, the erase information indicating the erase count corresponding to the memory block.

In some possible implementations, the memory controller is configured to: determine the first voltage based on the erase count; and send the erase operation instruction to the memory, the erase operation instruction further comprising information of the first voltage.

In some possible implementations, the first voltage is smaller when the erase count is larger.

In some possible implementations, the memory controller is configured to: determine the first voltage based on a preset formula V₁=V_{fresh}−n×V_{offset} according to the erase count, wherein V₁ is the first voltage, V_{fresh} is a preset initial first voltage, n is the erase count, and V_{offset} is a preset offset voltage.

In some possible implementations, the memory controller is configured to: determine the first voltage by querying a preset mapping table according to the erase count, wherein the mapping table comprises a mapping relationship between the erase count and the first voltage.

In some possible implementations, the memory is further configured to: in response to the erase operation instruction, apply an erase voltage to a bit line coupled with the memory block or a source line coupled with the memory block, the erase voltage being greater than the first voltage.

In some possible implementations, the memory is further configured to: in response to the erase operation instruction, apply a second voltage to the dummy word line coupled with the memory block before the bit line voltage or the source line voltage of the memory block rises to the first voltage.

In some possible implementations, the memory is further configured to: in response to the erase operation instruction, apply a second voltage to a word line coupled with the memory block.

In some possible implementations, the second voltage comprises a ground voltage.

In a second aspect, a memory is provided. The memory comprises a peripheral circuit and a memory array, wherein the peripheral circuit is coupled with the memory array. The peripheral circuit is configured to: in response to an erase operation instruction, when a bit line voltage or a source line voltage of a memory block having data to be erased in the memory array rises to a first voltage, set a dummy word line coupled with a memory block to a floating state, wherein the first voltage is related to an erase count of the memory block.

In some possible implementations, the first voltage is smaller when the erase count is larger.

In some possible implementations, the peripheral circuit is further configured to: in response to the erase operation instruction, apply an erase voltage to a bit line coupled with the memory block or a source line coupled with the memory block, the erase voltage being greater than the first voltage.

In some possible implementations, the peripheral circuit is further configured to: in response to the erase operation instruction, apply a second voltage to the dummy word line coupled with the memory block before the bit line voltage or the source line voltage of the memory block rises to the first voltage.

In some possible implementations, the peripheral circuit is further configured to: in response to the erase operation instruction, apply a second voltage to a word line coupled with the memory block.

In some possible implementations, the second voltage comprises a ground voltage.

In some possible implementations, the peripheral circuit is further configured to: send erase information to the memory controller, the erase information indicating the erase count corresponding to the memory block.

In a third aspect, an operation method of a memory is provided. The operation method comprises: in response to an erase operation instruction, when a bit line voltage or a source line voltage of a memory block having data to be erased rises to a first voltage, setting a dummy word line coupled with a memory block to a floating state, wherein the first voltage is related to an erase count of the memory block.

In some possible implementations, the first voltage is smaller when the erase count is larger.

In some possible implementations, the operation method further comprises: in response to the erase operation instruction, applying an erase voltage to a bit line coupled with the memory block or a source line coupled with the memory block, the erase voltage being greater than the first voltage.

In some possible implementations, the operation method further comprises: in response to the erase operation instruction, applying a second voltage to the dummy word line coupled with the memory block before the bit line voltage or the source line voltage of the memory block rises to the first voltage.

In some possible implementations, the operation method further comprises: in response to the erase operation instruction, applying a second voltage to a word line coupled with the memory block.

In some possible implementations, the second voltage comprises a ground voltage.

In some possible implementations, the operation method further comprises: sending erase information to the memory controller, the erase information indicating the erase count corresponding to the memory block.

In a fourth aspect, a computer apparatus is provided, which comprises a processor and a readable storage medium coupled with the processor, wherein the readable storage medium stores an executable instruction that, when being executed by the processor, can implement the method of any of the implementations in the third aspect.

In a fifth aspect, a computer readable storage medium is provided, which stores a computer executable instruction that, after being executed, can implement the method of any of the implementations in the third aspect.

Those skilled in the art may clearly appreciate that, for ease and simplicity of description, in the above examples, the descriptions of various examples have their own emphases, and portions of some example that are not described in detail may be referred to corresponding processes in the aforementioned method examples, which are no longer repeated herein.

In several examples provided by the present disclosure, it is to be understood that, the provided memory system, memory, and operation memory of a memory may be implemented in other manners. For example, the division of a certain module is merely a logical functional division. In a real implementation, there may be another division manner. For example, a plurality of units or components may be combined or may be integrated into another system, or some features may be ignored or not performed.

Those of ordinary skills in the art can recognize that the modules and algorithm operations of the examples as described in conjunction with the examples disclosed herein can be implemented in electronic hardware, or a combination of computer software and electronic hardware. Whether these functions are implemented in a hardware or software depends on particular applications and design constraints of the technical solution. Professional technicians can implement the described function using different methods for each particular application, but such implementation should not be considered as going beyond the scope of the present disclosure.

The above descriptions are merely example implementations of the present disclosure, but the protection scope of the present disclosure is not limited thereto. Any variation or replacement readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory system, comprising a memory and a memory controller, wherein the memory controller is coupled with the memory; and
the memory controller is configured to:
send an erase operation instruction to the memory, the erase operation instruction including information of a memory block having data to be erased in the memory; and
the memory is configured to: in response to the erase operation instruction, set a dummy word line coupled with the memory block to a floating state when a bit line voltage or a source line voltage of the memory block rises to a first voltage, wherein the first voltage is related to an erase count of the memory block.

2. The memory system of claim 1, wherein the memory is further configured to send erase information to the memory controller, the erase information indicating the erase count corresponding to the memory block.

3. The memory system of claim 1, wherein the memory controller is configured to:
determine the first voltage based on the erase count; and
send the erase operation instruction to the memory, the erase operation instruction further including information of the first voltage.

4. The memory system of claim 1, wherein the first voltage is smaller when the erase count is larger.

5. The memory system of claim 4, wherein the memory controller is configured to:
determine the first voltage based on a preset formula V₁=V_{fresh}−n×V_{offset} according to the erase count,
wherein V₁ is the first voltage, V_{fresh} is a preset initial first voltage, n is the erase count, and V_{offset} is a preset offset voltage.

6. The memory system of claim 4, wherein the memory controller is configured to determine the first voltage by querying a preset mapping table according to the erase count, wherein the preset mapping table includes a mapping relationship between the erase count and the first voltage.

7. The memory system of claim 1, wherein the memory is further configured to, in response to the erase operation instruction, apply an erase voltage to a bit line coupled with the memory block or a source line coupled with the memory block, the erase voltage being greater than the first voltage.

8. The memory system of claim 1, wherein the memory is further configured to, in response to the erase operation instruction, apply a second voltage to the dummy word line coupled with the memory block before the bit line voltage or the source line voltage of the memory block rises to the first voltage.

9. The memory system of claim 1, wherein the memory is further configured to, in response to the erase operation instruction, apply a second voltage to a word line coupled with the memory block.

10. The memory system of claim 8, wherein the second voltage includes a ground voltage.

11. A memory, comprising a peripheral circuit and a memory array, wherein the peripheral circuit is coupled with the memory array, and the peripheral circuit is configured to:
in response to an erase operation instruction, when a bit line voltage or a source line voltage of a memory block having data to be erased in the memory array rises to a first voltage, set a dummy word line coupled with a memory block to a floating state,
wherein the first voltage is related to an erase count of the memory block.

12. The memory of claim 11, wherein the first voltage is smaller when the erase count is larger.

13. The memory of claim 11, wherein the peripheral circuit is further configured to: in response to the erase operation instruction, apply an erase voltage to a bit line coupled with the memory block or a source line coupled with the memory block, the erase voltage being greater than the first voltage.

14. The memory of claim 11, wherein the peripheral circuit is further configured to, in response to the erase operation instruction, apply a second voltage to the dummy word line coupled with the memory block before the bit line voltage or the source line voltage of the memory block rises to the first voltage.

15. The memory of claim 11, wherein the peripheral circuit is further configured to, in response to the erase operation instruction, apply a second voltage to a word line coupled with the memory block.

16. The memory of claim 14, wherein the second voltage includes a ground voltage.

17. The memory of claim 11, wherein the peripheral circuit is further configured to send erase information to a memory controller, the erase information indicating the erase count corresponding to the memory block.

18. An operation method of a memory, comprising:
in response to an erase operation instruction, when a bit line voltage or a source line voltage of a memory block having data to be erased rises to a first voltage, setting a dummy word line coupled with the memory block to a floating state,
wherein the first voltage is related to an erase count of the memory block.

19. The operation method of claim 18, wherein the first voltage is smaller when the erase count is larger.

20. The operation method of claim 18, further including, in response to the erase operation instruction, applying an erase voltage to a bit line coupled with the memory block or a source line coupled with the memory block, the erase voltage being greater than the first voltage.
